(19) United States
(12) Patent Application Publication
(10) Pub. No.: US 2005/0098873 A1
(43) Pub. Date: May 12, 2005

(54) Stacked module systems and methods

(75) Inventor: James Douglas Wehrly JR., Austin, TX (US)

Correspondence Address: J. SCOTT DENKO, ANDREWS & KURTH LLP, 111 CONGRESS AVE., SUITE 1700, AUSTIN, TX, 78701, US

(73) Assignee: Staktek Group L.P.

(21) Appl. No.: 11/015,521

(22) Filed: Dec. 17, 2004

Related U.S. Application Data
(63) Continuation-in-part of application No. 10/845,029, filed on May 13, 2004.
Application No. 10/845,029 is a continuation-in-part of application No. PCT/US03/29000, filed on Sep. 15, 2003.

(51) Int. Cl. H01L 23/48

(52) U.S. Cl. 257/692

(57) ABSTRACT

The present invention stacks chip scale-packaged integrated circuits (CSPs) into modules that conserve PWB or other board surface area. The CSPs are connected with flex circuitry. Preferably, a form standard is disposed along the lower surface of the CSPs. The form standard can take many configurations and may be used where flex circuits are used to connect CSPs to one another in stacked modules. An adhesive attaches the form standard to the flex circuitry. The adhesive preferably is laminated to the flex circuitry in a region larger than the cross section of the form standard, to leave portions of the flex circuitry with extended adhesive. Such portions, in a preferred embodiment, provide physical support for the flex circuitry in a manner devised to control the bend radius. In a preferred embodiment, the form standard will be devised of heat transference material, preferably a metal such as copper, for example.

### RELATED APPLICATIONS

This application is a continuation-in-part of U.S. patent application Ser. No. 10/845,029, filed May 13, 2004, pending, which application is a continuation-in-part of PCT Application No. PCT/US03/29000, filed September 15, 2003, pending. U.S. patent application Ser. No. 10/485,029 and PCT Application No. PCT/US03/29000 are hereby incorporated by reference.

### TECHNICAL FIELD

The present invention relates to aggregating integrated circuits and, in particular, to stacking integrated circuits in chip-scale packages.

### BACKGROUND OF THE INVENTION

A variety of techniques are used to stack packaged integrated circuits. Some methods require special packages, while other techniques stack conventional packages.

The predominant package configuration employed during the past decade has encapsulated an integrated circuit (IC) in a plastic surround typically having a rectangular configuration. The enveloped integrated circuit is connected to the application environment through leads emergent from the edge periphery of the plastic encapsulation. Such “leaded packages” have been the constituent elements most commonly employed by techniques for stacking packaged integrated circuits.

Leaded packages play an important role in electronics, but efforts to miniaturize electronic components and assemblies have driven development of technologies that preserve circuit board surface area. Because leaded packages have leads emergent from peripheral sides of the package, leaded packages occupy more than a minimal amount of circuit board surface area. Consequently, alternatives to leaded packages known as chip scale packaging or “CSP” have recently gained market share.

CSP refers generally to packages that provide connection to an integrated circuit through a set of contacts (often embodied as “bumps” or “balls”) arrayed across a major surface of the package. Instead of leads emergent from a peripheral side of the package, contacts are placed on a major surface and typically emerge from the planar bottom surface of the package. The absence of “leads” on package sides renders most stacking techniques devised for leaded packages inapplicable for CSP stacking.

A variety of previous techniques for stacking CSPs typically present complex structural arrangements and thermal or high frequency performance issues. For example, thermal performance is a characteristic of importance in CSP stacks. Further, many stacking techniques result in modules that exhibit profiles taller than may be preferred for particular applications.

What is needed, therefore, is a technique and system for stacking CSPs that provides a thermally efficient, reliable structure that performs well at higher frequencies but does not add excessive height to the stack yet allows production at reasonable cost with readily understood and managed materials and methods.

### SUMMARY OF THE INVENTION

The present invention stacks chip scale-packaged integrated circuits (CSPs) into modules that conserve PWB or other board surface area. Although the present invention is applied most frequently to chip scale packages that contain one die, it may be employed with chip scale packages that include more than one integrated circuit die.

Multiple numbers of CSPs may be stacked in accordance with the present invention. The CSPs employed in stacked modules devised in accordance with the present invention are connected with flex circuitry. That flex circuitry may exhibit one or two or more conductive layers with preferred embodiments having two conductive layers.

A form standard is disposed along a planar surface of one or more CSPs in a stacked module. Preferably, the form standard is disposed along the lower planar surface. The form standard can take many configurations and may be used where flex circuits are used to connect CSPs to one another in stacked modules. An adhesive preferably attaches the form standard to the flex circuitry and preferably is laminated to the flex circuitry in a region larger than the cross section of the form standard, to leave portions of the flex circuitry with extended adhesive. Such portions, in a preferred embodiment, provide physical support for the flex circuitry in a manner devised to control the bend radius. In a preferred embodiment, the form standard will be devised of heat transference material, preferably a metal such as copper, for example.

### SUMMARY OF THE DRAWINGS

FIG. 1 is an elevation view of a high-density circuit module devised in accordance with a preferred embodiment of the present invention.

FIG. 2 is an elevation view of a four-level module devised in accordance with a preferred embodiment of the present invention.

FIG. 3 is an enlarged depiction of the area marked “A” in FIG. 2.

FIG. 4 is a view of a form standard employed in a preferred embodiment of the present invention.

FIG. 5 is a plan view with partial cutaway from below of a preferred embodiment of the present invention.

FIG. 6 is a cross-sectional view of one layer of a module without a form standard or an adhesive extension.

FIG. 7 is a cross-sectional view of a module devised in accordance with an alternative embodiment of the present invention.

FIG. 8 depicts a unit that may be employed in preferred embodiments of the present invention.

FIG. 9 depicts a sectional view of a connective area and a layered construction for a preferred flex circuitry employed in a preferred embodiment of the present invention.

FIG. 10 depicts a sectional view of a connective area and layered construction for an alternative preferred flex circuitry employed in a preferred embodiment of the present invention.

FIG. 11 is a flow chart of an assembly process for a two-high module according to a embodiment of the present invention.

FIG. 12 depicts a unit devised in accordance with another alternative of the present invention.

### DESCRIPTION OF PREFERRED EMBODIMENTS

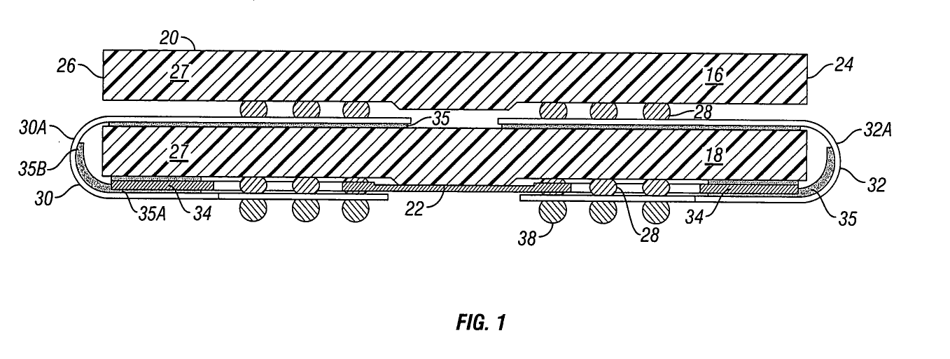

FIG. 1 is an elevation view of module 10 devised in accordance with a preferred embodiment of the present invention. In this embodiment, module 10 includes upper CSP 16 and lower CSP 18. Each of the constituent CSPs has an upper surface 20 and a lower surface 22 and opposite lateral edges 24 and 26 and includes at least one integrated circuit typically surrounded by a plastic body 27. The body need not be plastic, but a large majority of packages in CSP technologies are plastic. Those of skill will realize that the present invention may be devised to create modules with different size CSPs and that the constituent CSPs may be of different types within the same module 10. For example, one of the constituent CSPs may be a typical CSP having lateral edges 24 and 26 that have an appreciable height to present a “side” while other constituent CSPs of the same module 10 may be devised in packages that have lateral edges 24 and 26 that are more in the character of an edge rather than a side having appreciable height.

The invention is used with CSP packages of a variety of types and configurations such as, for example, those that are die-sized, as well those that are near chip-scale as well as the variety of ball grid array packages known in the art. It may also be used with those CSP-like packages that exhibit bare die connectives on one major surface. Thus, the term CSP should be broadly considered in the context of this application. Collectively, these will be known herein as chip scale packaged integrated circuits (CSPs) and preferred embodiments will be described in terms of CSPs, but the particular configurations used in the explanatory figures are not, however, to be construed as limiting. For example, the elevation view of FIG. 1 depicts a CSP of a particular profile known to those in the art, but it should be understood that the figures are exemplary only. The invention may be employed to advantage in the wide range of CSP configurations available in the art where an array of connective elements is available from at least one major surface. The invention is advantageously employed with CSPs that contain memory circuits, but may be employed to advantage with logic and computing circuits where added capacity without commensurate PWB or other board surface area consumption is desired.

Typical CSPs, such as, for example, ball-grid-array (“BGA”), micro-ball-grid array, and fine-pitch ball grid array (“FBGA”) packages have an array of connective contacts embodied, for example, as leads, bumps, solder balls, or balls that extend from lower surface 22 of a plastic casing in any of several patterns and pitches. An external portion of the connective contacts is often finished with a ball of solder. Shown in FIG. 1 are contacts 28 along lower surfaces 22 of the illustrated constituent CSPs 16 and 18. Contacts 28 provide connection to the integrated circuit or circuits within the respective packages. The depicted contacts 28 have been compressed prior to the complete construction of module 10. However, those of skill should understand that although contacts 28 as depicted in FIG. 1 are compressed, contacts 28 of CSPs employed in other embodiments of the invention need not be necessarily compressed or reduced in their height above the planar surface above which such contacts typically rise. Another preferred embodiment does not have such modifications to contacts 28.

Flex circuits 30 and 32 are shown connecting the constituent CSPs of the module of FIG. 1. The entire flex circuit may be flexible or, as those of skill in the art will recognize, a PCB structure made flexible in certain areas to allow conformability around CSPs and rigid in other areas for planarity along CSP surfaces may be employed as an alternative flex circuit in the present invention. For example, structures known as rigid-flex may be employed. More than one flex circuit may be employed to implement the connections between constituent CSPs in a module 10.

As shown in FIG. 1, a form standard 34 is disposed along lower planar surface 22 of body 27 of CSPs 16 and 18 in stacked module 10. Form standard 34 is disposed along a surface of a CSP even if literally separated from that surface by adhesive, for example. In this embodiment, form standard 34 is attached to flex circuits 30 and 32 with adhesive 35. Adhesive 35 has portion 35A adjacent to form standard 24, and portion 35B extending beyond the lateral extent of form standard 34. Portion 35B may provide a number of benefits to the structure and assembly of module 10. For example, the extension of adhesive portion 35B onto flex circuits 30 and 32 may help control the bend radius of curves 30A and 32A linking those portions of flex circuits 30 and 32 below CSP 18 to those portions above CSP 18. Such bend radius control may, in some embodiments, may create a simpler manufacturing process than that achieved by, for example, use of a form standard 34 that has curved supporting portions.

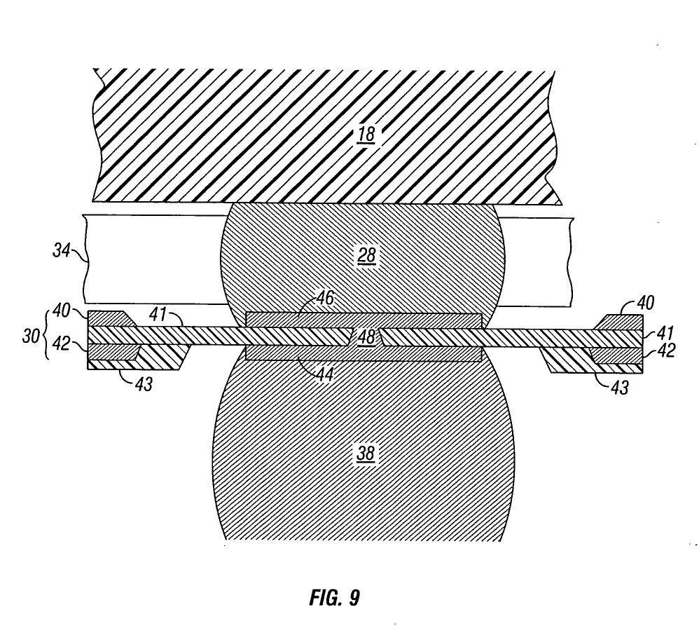

Form standard 34 may take many configurations. A preferred embodiment has form standard 34 having a lateral extent smaller than CSP 18. Other embodiments, such as the exemplar embodiment depicted in FIG. 8, have a form standard 34 with a lateral extent larger than CSP 18. Other examples of embodiments have a downward opening form standard shown in pending U.S. patent application Ser. No. 10/453,398, filed Jun. 3, 2003, commonly owned by the assignee of the present invention. In some cases, embodiments that employ downward opening form standards that are disposed across the upper surface of and arc underneath the lower surface of the CSP with which the form standard is associated may exhibit higher profiles. Module 10 exhibits module contacts 38 through which module 10 connects to application environments in a preferred embodiment. Those of skill will recognize that module contacts 38 are not required to connect module 10 to an application environment and other connective strategies may be employed such as, for example, direct pad to pad connection schemes.

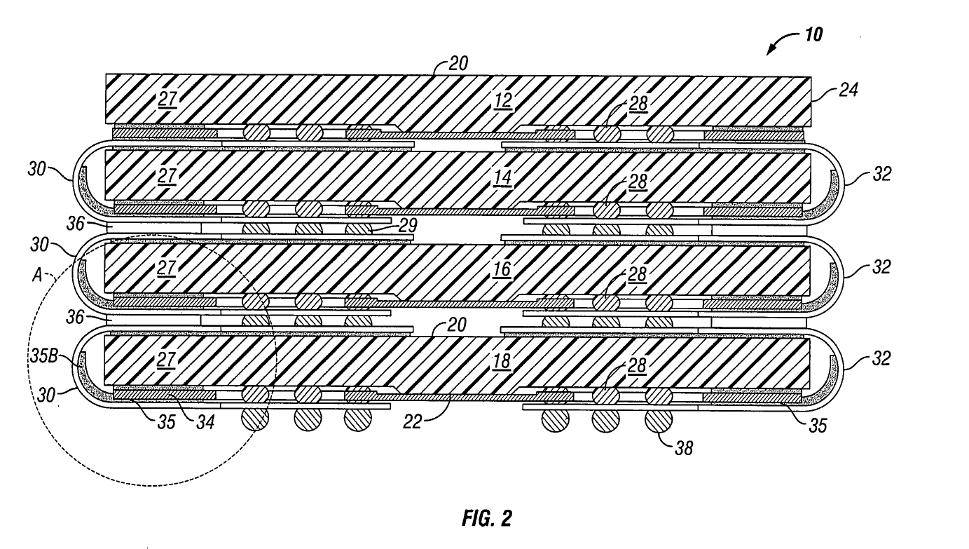

FIG. 2 depicts a four-level high embodiment of module 10 that employs four form standards 34 with a form standard 34 associated with each of CSPs 12, 14, 16 and 18. Those of skill will recognize that each level in module 10 need not have a form standard but where maximum heat extraction is desired, use of multiple form standards 34 is preferred. Flex circuits 30 and 32 in FIG. 2 have adhesive portions or extended adhesive portions 35B of adhesive 35. In this embodiment, form standards 34 extend past the edge of the depicted CSPs. Other embodiments may extend even further, may not extend, or may have other shapes or features along the lateral sides of form standard 34.

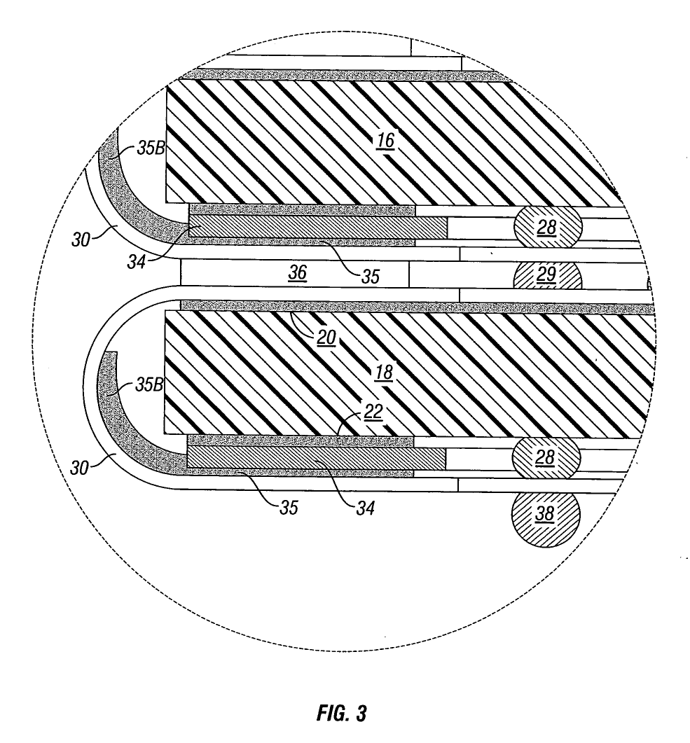

FIG. 3 is an enlarged depiction of the area marked “A” in FIG. 2. The connection strategy employed in module 10 as depicted in FIG. 2 and shown in greater detail in FIG. 3, includes a connective element 29 which, in a preferred embodiment, is a contact formed from reflowed solder paste. The depiction of FIG. 3 is not to scale connective element 29 will exhibit less height than contact 28 in one preferred embodiment. When module 10 includes more than two CSPs, use of connective elements 29 to connect the flex circuitry at one level to the flex circuitry at a next level is preferred. Where a two-CSP module 10 is devised, the upper CSP 16 will not, in a preferred embodiment, have flex circuitry about it and, consequently, will not, in preferred embodiments, employ connective elements 29. In a two-CSP module 10, contacts 28 of upper CSP 16 directly contact the flex circuitry that is associated with lower CSP 18. Form standard 34 may be fixed to the lower (or upper) surface of the respective CSP with an adhesive 36 which preferably is thermally conductive.

Form standard 34 is, in a preferred embodiment, devised from nickel-plated copper to create a mandrel that mitigates thermal accumulation while providing a standard sized form about which flex circuitry is disposed. Form standard 34 may take other shapes and forms that are coincident with the respective CSP body. It also need not be thermally enhancing although such attributes are preferable. The form standard 34 allows the invention to be employed with CSPs of varying sizes, while articulating a single set of connective structures useable with the varying sizes of CSPs. Thus, a single set of connective structures such as flex circuits 30 and 32 (or a single flexible circuit in the mode where a single flex is used in place of the flex circuit pair 30 and 32) may be devised and used with the form standard 34 method and/or systems disclosed herein to create stacked modules with CSPs having different-sized packages. This will allow the same flex circuitry design to be employed to create iterations of a stacked module 10 from constituent CSPs having a first arbitrary dimension X across attribute Y (where Y may be, for example, package width), as well as modules 10 from constituent CSPs having a second arbitrary dimension X prime across that same attribute Y. Thus, CSPs of different sizes may be stacked into modules 10 with the same set of connective structures (i.e. flex circuitry). Further, as those of skill will recognize, mixed sizes of CSPs may be implemented into the same module 10.

In a preferred embodiment, portions of flex circuits 30 and 32 may be attached to form standard 34 by adhesive 35, which, in a preferred embodiment, is a laminate tape adhesive. Other methods for attaching form standard 34 to flex circuitry may be employed in the present invention including, for example, liquid adhesive. Preferably, the adhesive will be thermally conductive. The depicted adhesive 35 is preferably disposed, after assembly, over a large portion of the curve connecting the depicted upper and lower portions of flex circuit 30. As shown in FIG. 3, adhesive extension portion 35B rises past the midpoint or vertical portion of the depicted curve. Other embodiments may use a smaller portion 35B, or a larger portion 35 B that may extent further along the depicted curve or cover the entire length of the depicted curve.

While in this embodiment portion 35B is depicted as increasing in thickness where it emerges from underneath form standard 34, other embodiments may have a uniform thickness for adhesive 35B. Still other embodiments may use a thinner portion 35B or one with a varied thickness. A tape laminate adhesive with uniform thickness is preferred. Further, adhesive may be used to affix layers or tapes of other materials to the depicted portion of the flex circuit. Materials such as, for example, polyamide tape or plastic may help control the mechanical stability and bend radius of flex circuit 30.

Further, while adhesive extension 35B is shown as being contiguous with the adhesive 35 attaching form standard 34 to flex circuit 30, other embodiments may employ a separate portion of adhesive disposed along the depicted curve. While such adhesive is preferably along the inside surface of the depicted curve, the surface facing the CSP, other embodiments may employ such an adhesive portion on the outer surface. The inner surface is preferred for most applications.

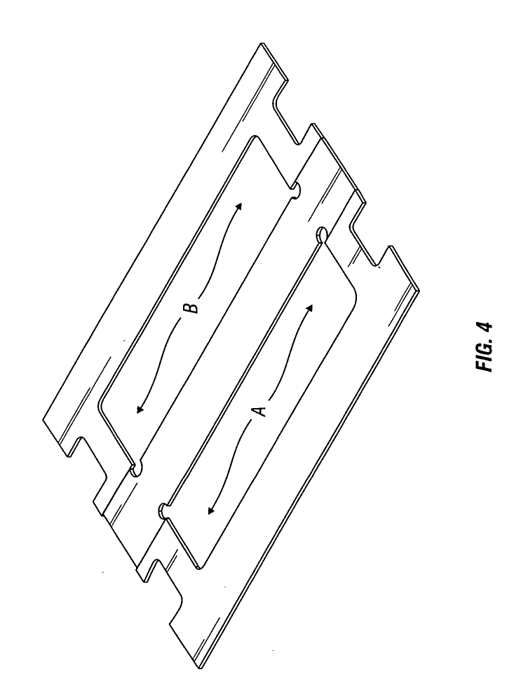

FIG. 4 illustrates an exemplar form standard 34 that may be employed in some preferred embodiments of the present invention. Form standard 34 as depicted in the preferred embodiment of FIG. 4 is comprised of nickel-plated copper and exhibits two windows identified by references A and B to allow the array of contacts 28 that rise above lower surface 22 of the respective CSP to readily pass through form standard 34. Form standard 34 may take other configurations and may, for example, be devised in more than one piece or have only one piece with only one window.

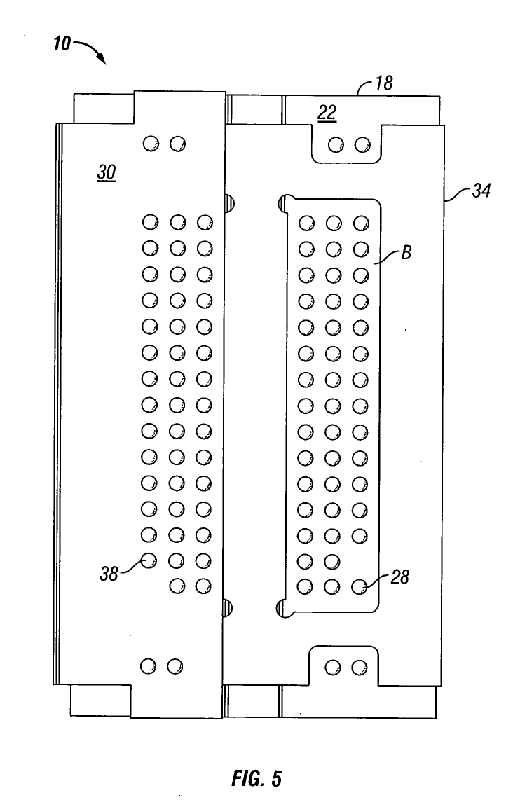

FIG. 5 is a plan view of an exemplar module 10 from below depicting an exemplar module 10 in which flex circuit 32 has been deleted to allow a view of the relationship between form standard 34 passing along lower planar surface 22 of CSP 18 and the flex circuitry employed in the module. On the right-hand side of the view of FIG. 5, and visible through window B of form standard 34, contacts 28 are shown rising from lower surface 22 of CSP 18 and projecting into window B. On the left-hand side of the view of FIG. 5, flex circuit 30 is represented as being disposed over part of form standard 34 and substantially all of window A of form standard 34. Module contacts 38 are shown along flex circuit 30.

The depicted edge of form standard 34 is outside the lateral extent of CSP 18. Other embodiments may have extend further outside. Still other embodiments may have a form standard 34 with a lateral extent smaller than that of CSP 18.

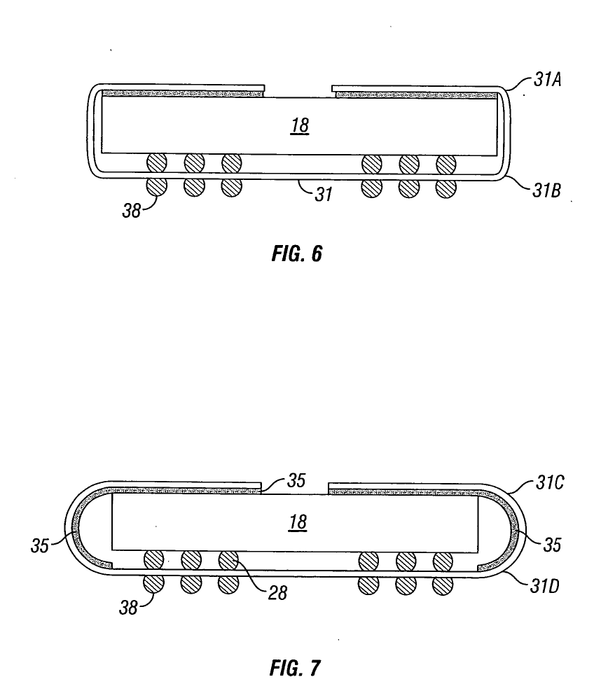

FIG. 6 is a cross-sectional view of one layer of a module without a form standard 34 or an adhesive extension 35B. As shown, flex circuit 31 has sharp comers 31A and 31B which may be deleterious to the mechanical integrity of flex circuit 31 and may exhibit further problems such as, for example, difficulty in manufacturing and poor thermal performance.

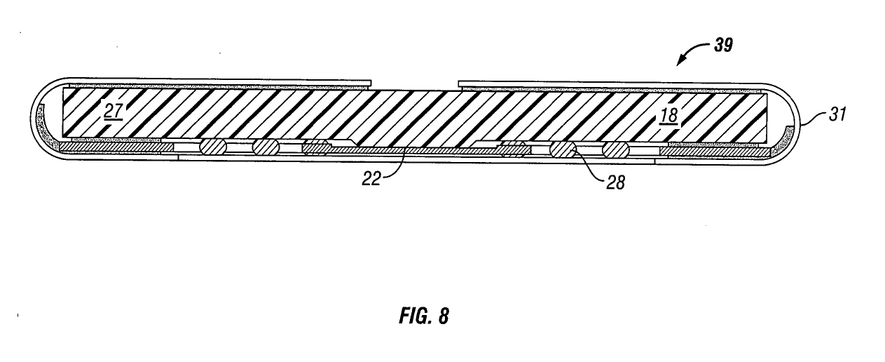

FIG. 7 is a cross-sectional view of a module 10 devised in accordance with an alternative embodiment of the present invention. Adhesive 35 is shown attaching flex circuit 31 to the upper major surface of CSP 18. Portions of adhesive 35 extend beyond the lateral extent of CSP 18 and are disposed along the depicted curves in flex circuit 31. Such portions may help produce comers 31C and 31D which are rounded and more structurally beneficial than the comers 31A and 31B in FIG. 6. Such portions of adhesive may also help control the bend radius of flex circuit 31 in the depicted curves.

FIG. 8 depicts unit 39 devised in accordance with one preferred embodiment of the present invention. As those of skill will note, the flex circuitry employed in exemplar unit 39 is a single flex circuit 31 but as depicted in other embodiments, multiple flex circuits may also provide the flex circuitry employed in preferred embodiments of the invention. Multiple iterations of unit 39 may be stacked, preferably with earlier-described connectives 29 realizing the connection between constituent levels, to create a multi-level module 10 or, when combined with an upper CSP 16, a two-level module 10.

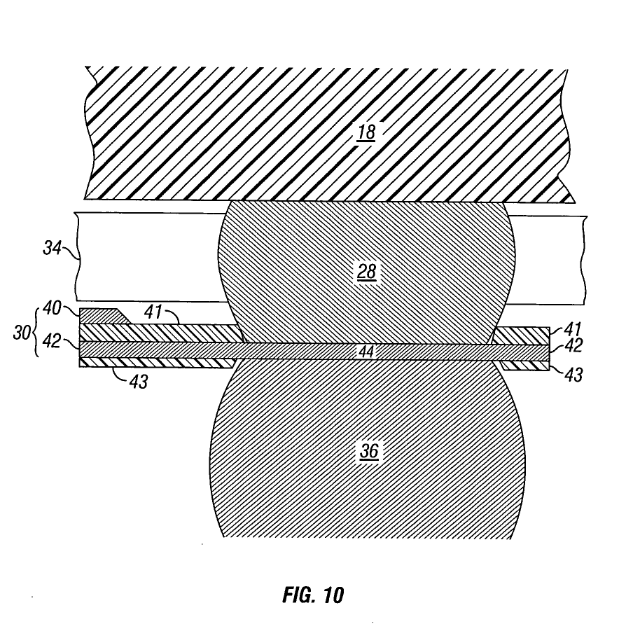

FIG. 9 is a cross-sectional view of a portion of a preferred embodiment taken through a window of form standard 34 depicting a preferred construction for flex circuitry which, in the depicted embodiment, is in particular, flex circuit 30 which comprises two conductive layers 40 and 42 separated by intermediate layer 41. Preferably, the conductive layers are metal such as alloy 110.

With continuing reference to FIG. 9, optional outer layer 43 is shown over conductive layer 42 and, as those of skill will recognize, other additional layers may be included in flex circuitry employed in the invention. Flex circuits that employ only a single conductive layer such as for example, those that employ only a layer such as conductive layer 42 may be readily employed in embodiments of the invention. The use of plural conductive layers provides, however, advantages and the creation of a distributed capacitance across module 10 intended to reduce noise or bounce effects that can, particularly at higher frequencies, degrade signal integrity, as those of skill in the art will recognize. In the depicted preferred embodiment, flex contact 44 at the level of conductive layer 42 and flex contact 46 at the level of conductive layer 40 provide contact sites to allow connection of module contact 38 and CSP contact 28 through via 48. Form standard 34 is seen in the depiction of FIG. 9 as contact 28 is within an opening of form standard 34 which, consequently, is not seen passing in front of contact 28 in the provided cross-sectional view.

FIG. 10 depicts a cross-sectional view of an alternative preferred construction in a contact area in a module 10 devised in accordance with a preferred embodiment of the invention.

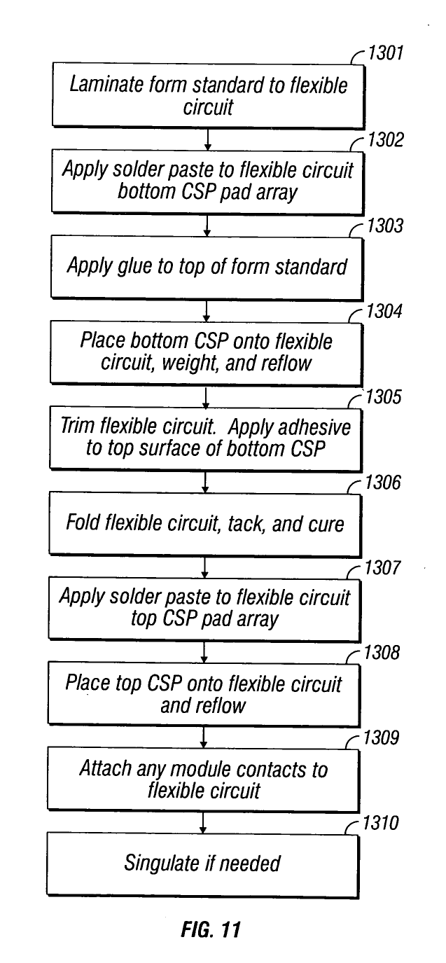

FIG. 11 is a flow chart of an assembly process for a module 10 according to one embodiment of the present invention. In this preferred assembly process in step 1301, one or more flexible circuits is first laminated with a form standard 34. Such lamination may be with tape adhesive or other types of adhesive, and preferably leaves an adhesive extension 35B.

Step 1302 applies solder paste to an array of CSP contacts disposed on the flexible circuitry to receive the lower CSP of the module. Step 1303 applies glue or other adhesive to the top of form standard 34. Step 1304 places the bottom CSP aligned with the contacts. Force or weight may be applied to the lower CSP to provide optimum positioning for reflow. The assembly is next reflowed to connect the lower CSP to the flexible circuit.

In step 1305, the flexible circuit may be trimmed to prepare it for its final configuration. Further, adhesive is applied to the top surface of the lower CSP for receiving the ends of the flexible circuit(s). In step 1306, the flexible circuit is folded, preferably over lateral sides CSP 18, and ends are tacked to the upper surface of CSP 18. The adhesive is next cured.

Step 1307 applies solder paste to flex contacts along the post-folded upper side of the flexible circuit(s). In embodiments having more than two layers, an assembled module having connecting elements 29 is next placed onto the flexible circuits. In this embodiment, a two-high module is assembled. Step 1308 places the top CSP along the contacts and reflows the solder paste and CSP contacts of the top CSP.

In step 1309, if employed, module contacts are added underneath the lower CSP. In step 1310, the module may be singulated if needed to split up any large flexible circuits that may have been employed to assemble more than one module simultaneously. Such conglomeration and singulation preferably occurs along a long dimension, such as the vertical long dimension shown in FIG. 5.

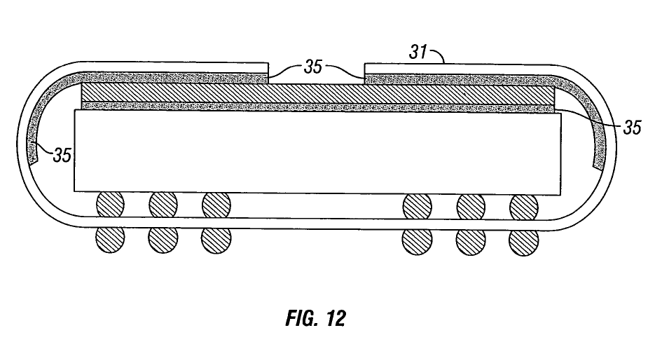

FIG. 12 depicts a unit 39 devised in accordance with another alternative of the present invention. The flex circuitry employed in exemplar unit 39 is a single flex circuit 31. Multiple iterations of unit 39 may be stacked, preferably with earlier-described connectives 29 realizing the connection between constituent levels, to create a multi-level module 10 or, when combined with an upper CSP 16, a two-level module 10. CSP 18 connects to a first set of flex contacts on the lower depicted portion of flex circuit 31. One or more upper CSPs are preferably placed onto similar flex contacts on the upward-facing surfaces of flex circuit 31.

In this embodiment, form standard 34 is disposed along the upper surface of CSP 18, and preferably attached with adhesive 35. Flex circuit 31 is wrapped about opposing lateral sides of CSP 18 and adhesively attached to form standard 34. The upper depicted adhesive connections in this embodiment have adhesive extensions that extend along the curve connecting the lower and upper portions of flex circuit 31.

Although the present invention has been described in detail, it will be apparent to those skilled in the art that the invention may be embodied in a variety of specific forms and that various changes, substitutions and alterations can be made without departing from the spirit and scope of the invention. The described embodiments are only illustrative and not restrictive and the scope of the invention is, therefore, indicated by the following claims.

1. A high-density circuit module comprising:
a first CSP having first and second lateral sides and upper and lower major surfaces with CSP contacts along the lower major surface;
a second CSP having first and second lateral sides and upper and lower major surfaces with CSP contacts along the lower major surface, the second CSP being in stacked disposition above the first CSP;
a form standard disposed along the lower major surface of the first CSP, the form standard having first and second edges defining a lateral extent of the form standard;
flex circuitry employed to connect the first and second CSPs,
adhesive connecting the form standard to the flex circuitry, an extended portion of the adhesive being adhered to a first portion of the flex circuitry, the first portion of the flex circuitry being outside of the lateral extent of the form standard.

2. The high-density circuit module of claim 1 in which the form standard exhibits an opening.

3. The high-density circuit module of claim 1 in which the form standard does not extend above a plane defined by the lower major surface of the first CSP.

4. The high-density circuit module of claim 2 in which the CSP contacts along the lower major surface of the first CSP project into the opening of the form standard.

5. The high-density circuit module of claim 1 in which the form standard exhibits at least two openings.

6. The high-density circuit module of claim 1 in which the form standard is attached to the first CSP with adhesive.

7. The high density circuit module of claim 1 in which the first portion of the flex circuitry is bent to form an curve.

8. The high-density circuit module of claim 1 in which the flex circuitry comprises first and second flex circuits.

9. The high-density circuit module of claim 1 in which the flex circuitry is disposed, in part, beneath the first CSP and, in part, above the first CSP.

10. The high-density circuit module of claim 1 in which the flex circuitry comprises at least two conductive layers.

11. The high-density circuit module of claim 1 in which the flex circuitry comprises two flex circuits and each of said flex circuits comprises at least two conductive layers.

12. The high-density circuit module of claim 1 further comprising a second form standard disposed along and extending beyond the lower major surface of the second CSP.

13. The high-density circuit module of claim 7 in which the extended portion of the adhesive is applied to the first portion of the flex circuitry to produce a desired thickness of the adhesive, the desired thickness devised to encourage a desired bend radius in the curve.

14. A method of making a circuit module comprising the steps of:
providing a first CSP having first and second lateral sides, a bottom major surface and a top major surface, and plurality of contacts arranged along the bottom major surface;
providing a second CSP;
providing flex circuitry having a first major side and a second major side, and a plurality of flex contacts on the first major side;
disposing a layer of adhesive along the first major side of at least a first portion of the flex circuitry;
disposing a form standard along the layer of adhesive such that the form standard partially covers the layer of adhesive, leaving at least one extended portion of the layer of adhesive;
attaching the first CSP to the flex contacts;
folding the flex circuitry about the form standard and the first CSP such that a second portion of the flex circuitry is disposed above the first CSP, and a third portion is formed into a fold between the first portion and the second portions, the at least one extended portion of the layer of adhesive extending along at least about ten percent of a height of the fold;
attaching the second CSP to the second portion of the flex circuitry.

15. The method of claim 14 in which the step of disposing the layer of adhesive increases a smallest bend radius that may be achieved when folding the flex circuitry.

16. The method of claim 14 in which the at least one extended portion of the layer of adhesive extends along more than fifty percent of the height of the fold.

17. The method of claim 14 in which the at least one extended portion of the layer of adhesive is devised to help control a bend radius of the flex circuitry.

18. The method of claim 14 in which the at least one extended portion of the layer of adhesive extends along more than thirty percent of the height of the fold.

19. A method of making a high-density circuit module comprising the steps of:
providing one or more flexible circuits each having a first major side and a second major side;
disposing adhesive along one or more first adhesive-bearing portions of each of the one or more flexible circuits;
folding the one or more flexible circuits to produce a bend along at least one of the one or more first adhesive-bearing portions of the one or more flexible circuits.

20. The method of claim 19 further comprising the step of attaching a first CSP to a plurality of flex contacts on the first major side of the one or more flexible circuits.

21. The method of claim 20 further comprising the step of disposing a form standard along the adhesive such that the form standard partially covers the adhesive, leaving at least one extended portion of the adhesive.

22. The method of claim 21 further comprising the step of attaching a second CSP to the one or more flexible circuits in a stacked disposition above the first CSP.

23. The method of claim 20 further comprising the step of attaching a second CSP to the one or more flexible circuits in a stacked disposition above the first CSP.

24. The method of claim 19 in which the bend has a vertical portion, the adhesive-bearing portion extending from below the vertical portion to the vertical portion after the step of folding the one or more flexible circuits.

25. The method of claim 19 in which the bend has a vertical portion, the adhesive-bearing portion extending from below the vertical portion to above the vertical portion, and including the vertical portion, after the step of folding the one or more flexible circuits.

26. The method of claim 19 in which the bend has a vertical portion, the adhesive-bearing portion not extending above the vertical portion after the step of folding the one or more flexible circuits.

27. A unit for use in aggregating CSPs, the unit comprising:
a CSP, having upper and lower major surfaces;
a form standard disposed along and extending beyond the lower major surface, the form standard having first and second edges defining a lateral extent of the form standard; and
flex circuitry attached to the form standard, the flex circuitry having a first portion disposed outside of the lateral extent of the form standard;
adhesive attached to the first portion for the flex circuitry.

28. The unit of claim 27 in which the adhesive is applied to the first portion of the flex circuitry to produce a controlled thickness of the adhesive, the controlled thickness devised to encourage a desired bend radius for bending the flex circuitry.

29. The unit of claim 27 in which the adhesive is a laminate tape adhesive.

30. The unit of claim 27 in which the flex circuitry is bent in at least one place to form a curve connecting a portion of the flex circuitry above the CSP to a portion of the flex circuitry below the CSP, the curve containing at least part of the first portion of the flex circuitry.

31. The unit of claim 30 in which the first portion of the flex circuitry extends along a majority of the curve.

32. The unit of claim 30 in which the adhesive is disposed on an inside surface of the curve.
